(19) United States
(12) Patent Application Publication
(10) Pub. No.: US 2010/0120263 A1
(43) Pub. Date: May 13, 2010

(54) MICROWAVE ACTIVATION ANNEALING PROCESS

(76) Inventors: Fu-Kuo HSUEH, HsinChu City (TW); Yao-Jen Lee, HsinChu City (TW); Ching-Yi Wu, HsinChu City (TW)

Correspondence Address: BIRCH STEWART KOLASCH & BIRCH, PO BOX 747, FALLS CHURCH, VA, 22040-0747, US

(21) Appl. No.: 12/344,065

(22) Filed: Dec. 24, 2008

(30) Foreign Application Priority Data
Nov. 12, 2008 (TW) 097143763

(51) Int. Cl. H01L 21/02

(52) U.S. Cl. 438/795; 257/E21.002

(57) ABSTRACT

The present invention relates a microwave activation annealing process, which includes: the providing of a semiconductor process to form a semiconductor device on a substrate; activation: using a microwave device to perform microwave activation on the semiconductor device with frequency in the range of 2.45 GHz and 24.15 GHz and temperature in the range of 100° C. and 600° C.; annealing: using the microwave device to perform microwave annealing on the semiconductor device with frequency in the range 2.45 GHz to 24.15 GHz and temperature in the range 100° C. to 600° C.; by doing so, the present invention can, in the premise without the destruction of material property and structural interface and be able to shorten process time and enhance heating homogeneity, achieve the objective of activation annealing, hence, it can solve the defects caused by the heat treatment technique of prior art high temperature activation annealing.

### FIELD OF THE INVENTION

The present invention relates to a microwave activation annealing process, it especially relates to a microwave activation annealing process that won't destruct the material property and the structural interface but can shorten the process time and enhance the heating homogeneity.

### BACKGROUND OF THE INVENTION

In the high tech industries such as semiconductor packaging, optoelectronic and solar cell, etc., the work object must pass through the heat treatment process of one high temperature with subsequent low temperature cooling so that the work object can achieve the activation and the annealing purposes; currently, the commonly used heat treatment techniques include: high temperature furnace, LASER, Rapid Thermal Annealing (RTA), spike RTA, Flash Lamp Anneal, etc.

Generally speaking, the above mentioned work objects include the following three categories:

1. Si-Based Substrate, for example, Silicon Germanium, (SiGe), which can be used to manufacture semiconductor devices such as metal oxide semiconductor field effect transistor (MOSFET), Thin Film Transistor (TFT), etc.

2. Compound Substrate, for example, Germanium Arsenide (GaAs), which can be used to manufacture semiconductor devices such as: metal semiconductor field effect transistor (MESFET), bipolar junction transistor (BJT), etc.

3. Glass substrate and soft flexible substrate, for example, Polyimide (PI), which can be used to manufacture thin film transistor (TFT) or solar cell. To silicon-based substrate and compound substrate, it is through heat treatment process of 600° C.-1100° C. to ion implant or diffuse the impurity entering the lattice to the lattice point so that the original impurity will become dopant and can release electron or hole to achieve the electrical activation effect; meanwhile, the damages in the semiconductor due to ion implantation can be improved.

To the glass substrate and the soft flexible substrate, through the heating method, the Amorphous Silicon Layer is converted to Polysilicon or even Single Crystal Silicon so as to enhance the device characteristic of the semiconductor device; however, the glass substrate and the soft flexible substrate can not resist the high temperature process, hence, the activation process is changed to laser heating treatment.

However, under the current trend of small form factor and miniaturization for the high tech electronic product, the dimension of work object to be manufactured thus gradually diminish in its dimension, hence, the endurance of the work object on the high temperature generated in the activation procedure of the process is then limited and it thus leads to the drawbacks of the generation of thermal destruction on the object to be manufactured.

For example, the heat treatment process of furnace will generate high temperature which will destruct the material property, destruct the structural interface, result in junction diffusion and inter-diffusion, etc.; in addition, the longer process time needed by the furnace also makes some degrade on the process efficiency.

Furthermore, although the heat treatment process of RTA is very short, yet its high temperature still causes the drawbacks such as: damage of material the characteristics, damage of the structural interface and the inter-diffusion.

In addition, let's take the LASER heat treatment process as an example, although it has lower heat treatment temperature and smaller thermal damage and has the advantage of partial treatment, yet the entire process time is lengthened and it is impossible to provide good heating homogeneity.

To sum up, we can see that currently, in the high tech electronic industry, no matter the substrate is made of what material, the currently used high temperature activation annealing thermal treatment techniques have the drawbacks such as high temperature thermal damage, longer process time or heating homogeneity, etc.; if there is one activation annealing process that can solve simultaneously these drawbacks, it can for sure enhance the process efficiency and the industry development can be further promoted.

### SUMMARY OF THE INVENTION

Therefore, to solve the drawbacks generated by the above mentioned existed activation annealing heat treatment process, the inventor of the present invention thus work with all the efforts so as to solve the common issues in the prior art heat treatment process; after non-interrupted tests and efforts, the present invention is thus developed.

The main objective of the present invention is to provide a microwave activation annealing process which not only won't destruct the material property and the structural interface, but also can shorten process time and enhance heating homogeneity.

In order to achieve the objective of the above mentioned invention, the following technical means are taken; the microwave activation annealing process of the present invention includes:

providing a semiconductor process to for a semiconductor device on a substrate;

activation: using a microwave device to perform microwave activation on the semiconductor device, with microwave frequency in the range of 2.45 GHz to 24.15 GHz and activation temperature in the range of 100° C. to 600° C.;

annealing: using the microwave device to perform microwave annealing on the semiconductor device with frequency in the range of 2.45 GHz to 24.15 GHz, the temperature is in the range from 100° C. to 600° C.

Wherein the substrate is of single layer structure or multi-layer structure, with material of silicon-based substrate, compound substrate, glass substrate or flexible substrate; the silicon-based substrate is material of silicon, SiGe or silicon on insulator; the compound substrate material is of GeAs, InP, GaAs or AlGaAs; the flexible substrate is of material polyimide, polyethylene terephthalate, Polyethylene Naphthalate or synthesized paper.

The semiconductor device is nano electronic semiconductor device, metal oxide semiconductor field effect transistor, quantum well, metal semiconductor field effect transistor, field effect transistor with high electron mobility, bipolar junction transistor, light emitting diode, laser diode, thin film transistor or semiconductor device with PN junction.

Through the above mentioned method, the activation annealing process of the present invention of microwave activation annealing process, because the energy provided by the microwave can only be absorbed by the semiconductor device, the doped atom in the material of the object to be manufactured will rotate instead of vibrate so as to complete the bond repair; moreover, the air in the device and the corresponding container all will not generate heat, hence, the efficiency is very high; in addition, since the microwave can provide energy in a very quick way, temperature is very low and heating is very homogeneous, hence, it can improve the time-consuming, high temperature and bad homogeneity drawbacks generated in the commonly used thermal treatment techniques of high tech industries such as semiconductor packaging, optoelectronic and solar cell, etc.

### BRIEF DESCRIPTION OF THE DRAWINGS

FIG. 1 shows the flow chart of the microwave activation annealing process of the present invention.

FIG. 2 illustrates the deposition of epitaxial of the first embodiment of the present invention.

FIG. 3 illustrates the formation of N TYPE WELL and P type well of the first embodiment of the present invention.

FIG. 4 illustrates the formation of shallow trench isolation of the first embodiment of the present invention.

FIG. 5 illustrates the voltage adjustment and ion implantation of the N channel and P channel of the first embodiment of the present invention.

FIG. 6 illustrates the poly-silicon etching of the first embodiment of the present invention.

FIG. 7 illustrates the ion implantation of the extension part and source electrode/drain electrode of the N channel and B channel of the first embodiment of the present invention.

FIG. 8 illustrates the epitaxial way stacking of the second embodiment of the present invention.

FIG. 9 illustrates the metallic contact between source electrode and drain electrode of the second embodiment of the present invention.

FIG. 10 illustrates the definition and formation of the second embodiment of the present invention.

FIG. 11 illustrates the formation of the buffer layer and hydrogenated amorphous silicon of the third embodiment of the present invention.

FIG. 12 illustrates the definition and etching of the poly-silicon island of the third embodiment of the present invention.

FIG. 13 illustrates gate electrode deposition and gate electrode definition of the third embodiment of the present invention.

FIG. 14 illustrates ion implantation of the source electrode/drain electrode of the third embodiment of the present invention.

FIG. 15 is the numerical value comparison diagram of carrier concentration versus substrate depth of the present invention and conventional heat treatment process.

FIG. 16 shows the X ray diffraction diagram of the present invention and conventional heat treatment process.

FIG. 17 is the transmission electron microscope photo after microwave activation annealing of the present invention.

### DETAILED DESCRIPTION OF THE INVENTION

In the followings, different embodiments are used to describe the present invention; the described compositions, arrangements and steps, etc. are used to describe the embodiment content and are only examples instead of using to limit the present invention. In addition, in the disclosed content, the use of “and/or” is for briefing purpose; the descriptions of “cover” or “above” can include the direct contact and non-direct contact.

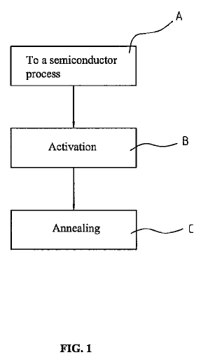

Please refer to FIG. 1, the microwave activation annealing process of the present invention includes the following steps:

providing a semiconductor process (A); forming a semiconductor device on a substrate;

activation (B); using a microwave device to perform microwave activation on the semiconductor device with microwave frequency in the range 2.45 GHz to 24.15 GHz and activation temperature in the range 100° C. to 600° C.;

annealing (C); using the device to perform microwave annealing on the semiconductor device with microwave frequency in the range 2.45 GHz to 24.15 GHz and annealing temperature in the range 100° C. to 600° C.

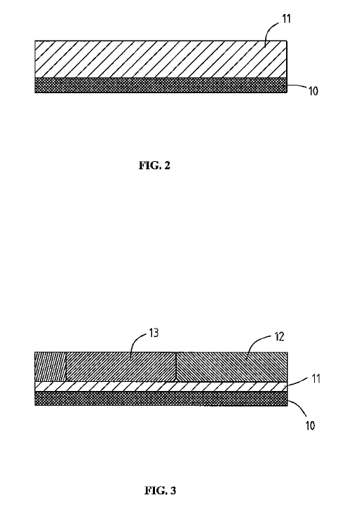

Please refer to FIG. 2 to FIG. 7, which is the first embodiment of the present invention; in the embodiment, the microwave activation annealing process of the present invention is applied in Complementary Metal Oxide Semiconductor Field Effect Transistor process; as shown in FIG. 2, silicon-based substrate is supplied to be used as P type bare wafer (10) and the P type bare wafer (10) is cleaned, then epitaxy deposition is performed to form a P type epitaxial layer (11); as shown in FIG. 3, photo mask is used on the P type epitaxial layer (11) to perform microlithography process so as to form a N well (12); meanwhile, the N well (12) is implanted with P ion, and a photo mask is further used on the P type epitaxial layer (11) to perform microlithography process to form P type well (13), then the P type well (13) is implanted with boron ion, and finally the photo resist is stripped.

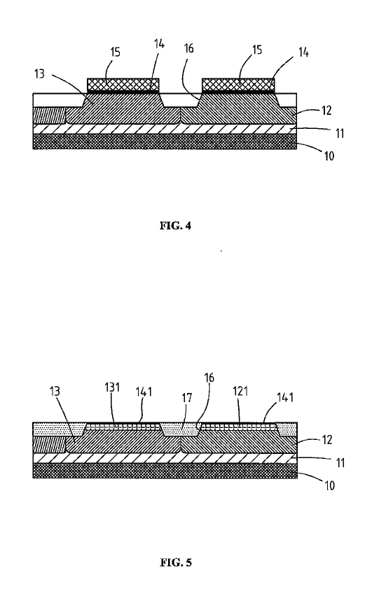

As shown in FIG. 4, above the N type well (12) and the P type well (13) is made with an pad oxide layer (14); meanwhile, Low Pressure Chemical Vapor Deposition (LPCVD) is used to deposit layer of silicon nitride layer (15) on the oxide layer (14), then a photo mask is used to perform lithography process so as to acquire a Shallow Trench Isolation (STI)(16), then the silicon nitride layer (15) is etched and then the oxide layer (14) and silicon is made.

As shown in FIGS. 4 and 5, after another deposition of a silicon nitride layer (15), High Density Plasma Chemical Vapor Deposition, (HDPCVD) is used to fill the Shallow Trench Isolation (STI) (16) with Undoped Silicon Glass (17), then Chemical Mechanical Polishing (CMP) is used to grind away the extra Undoped Silicon Glass (17) after Shallow Trench Isolation (STI) (16) is filled; meanwhile, the grinding action will stop at the silicon nitride layer (15), then the stripping of the silicon nitride and pad oxide will be performed and wafer will be cleaned; then a photo mask will be used to perform microlithography process so that the N well (12) will form a N channel (121) and start the threshold voltage V_{TH} adjustment, N channel V_{TH} adjustment and the implantation of phosphorus ion on the N channel (121); meanwhile, a photo mask is used for microlithography so that the P type well (13) will form a P channel (131) and start the threshold voltage V_{TH} adjustment, P channel V_{TH} adjustment and the implantation of boron ion on the P channel (131) so that the oxide layer (14) will become a gate electrode oxide layer (141).

As shown in FIG. 6, LPCVD method is used to deposit poly-silicon as poly-silicon gate electrode (18) on the gate electrode oxide layer (141), then a photo mask is used to perform microlithography process so as to achieve gate electrode and partial connection, then the poly-silicon that is not protected by the photo mask (19) is etched.

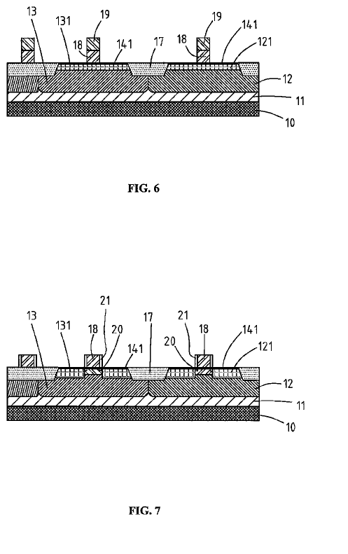

As shown in FIG. 7, a photo mask is used on the N channel (121) to form an extension part (20) of a doped drain electrode, and arsenic ion is implanted on the extension part (20); moreover, a photo mask is used to form an extension part (20) of a doped drain electrode on the P channel (131), and BF2 ion is implanted on the extension part, then a side wall spacer layer (21) is formed on both sides of poly-silicon gate electrode (18) of the N channel (121) and P channel (131); then a photo mask is used to form source electrode/drain electrode on the N channel (121) and to implant source electrode/drain electrode on the N channel (121), then a photo mask is used to form on the P channel (131) source electrode/drain electrode and to implant on the P channel (131) the source electrode/drain electrode; finally, microwave activation annealing is taken to perform activation and annealing steps.

In the microwave activation annealing process, a microwave device is used to perform the microwave activation on the complementary metal oxide semiconductor field effect transistor with microwave frequency of 2.45 GHz with activation temperature 320° C.; by doing so, the impurity within the lattice thus moves to the lattice point, and the original impurity thus becomes dopant and electron or hole is then released to generate electrical activation effect; in addition, as compared to the prior art of the need of high temperature from the thermal treatment technique of the direct application of energy heat source to the work object to be manufactured, the activation temperature for the microwave treatment in the present invention is obviously lower; because of this low temperature characteristic, the junction profile at the PN junction will not change due to inter-diffusion.

After microwave activation, the subsequent process is microwave annealing; the microwave annealing frequency of the complementary metal oxide semiconductor field effect transistor is also 2.45 GHz, the annealing temperature is also 320° C.; by doing so, the damaged lattice will get rearranged and the disordered lattice during the doping process will recover to normal lattice position; later on, new grain will be formed to replace the original deformed grain due to the internal stress; meanwhile, the large and small grain will merge to reduce the internal grain boundary number, then the composition of the complementary metal oxide semiconductor field effect transistor will be homogenized, and the residual stress will be removed and the needed physical property will be obtained.

Please refer to FIGS. 8 to 10, which is the second embodiment of the present invention; in the embodiment, the microwave activation annealing process of the present invention is used in Metal Semiconductor Field Effect Transistor process; as shown in FIG. 8, a compound substrate of GaAs semi-insulating substrate (30) is supplied, epitaxial way is used to stack in sequence a buffer layer (31), a Schottky layer (32) and a cap layer (33); then dry etching method is used to do dicing and mesa isolation to form several mutually separated blocks.

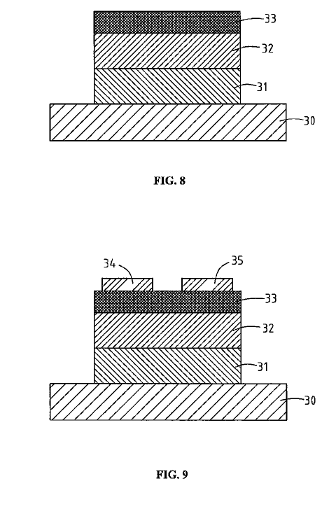

As shown in FIG. 9, on the cap layer (33) of one of the blocks, the microlithography process is used to form metal contact between the source electrode (34) and the drain electrode (35); then the microwave activation annealing is performed with microwave activation frequency of 5.8 GHz and microwave activation temperature of 320° C., and the microwave annealing frequency can also be 5.8 GHz with microwave annealing temperature also 320° C., hence the contact resistance between metal and the cap layer (33) can be reduced.

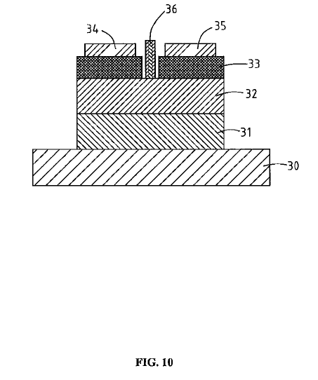

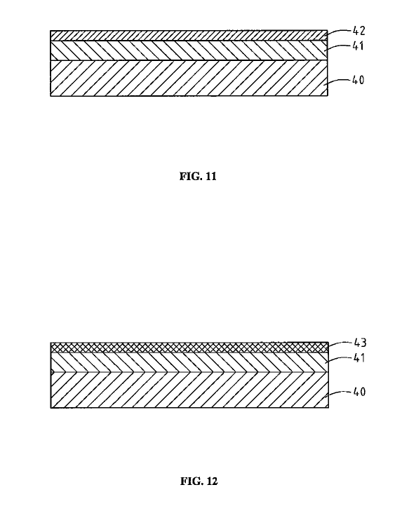

As shown in FIG. 10, finally, gate recess and gate formation for the gate electrode is performed to form a gate electrode (36) so as to complete the Metal Semiconductor Field Effect Transistor.

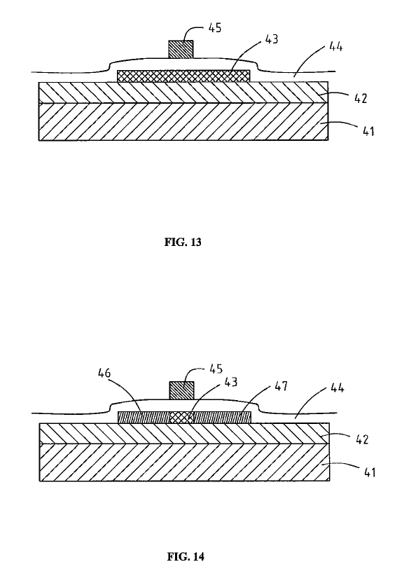

Please refer to FIG. 11 to FIG. 14, which is the third embodiment of the present invention; in the embodiment, the microwave activation annealing process of the present invention is used in a Thin Film Transistor process; as shown in FIG. 11, a glass substrate (40) is supplied and glass inspection is done to inspect if there are any defects on the glass substrate (40); then chemical vapor deposition (CVD) is used to deposit a silicon dioxide buffer layer (41) and on the silicon dioxide buffer layer (41) is then deposited again with a hydrogenated amorphous silicon (a-Si:H)(42); then a dehydrogenation step is used to strip off the hydrogen in the hydrogenated amorphous silicon (42).

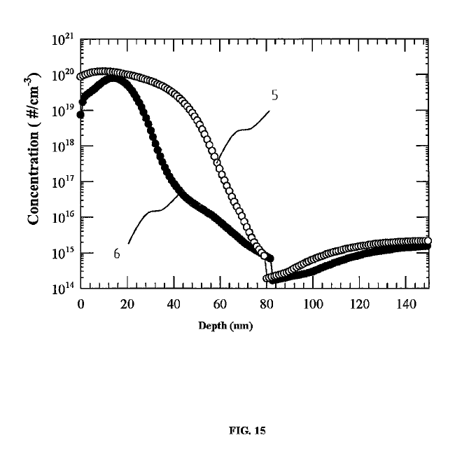

As shown in FIG. 12, then the next thing to do is crystallization, then the definition and etching of ploy-Si island (43) is done. As shown in FIG. 13, CVD is used to perform gate electrode dielectric layer deposition so as to form a gate dielectric layer (44) to cap poly-silicon island (43), then deposition and etching is done so as to form and define a gate electrode (45).

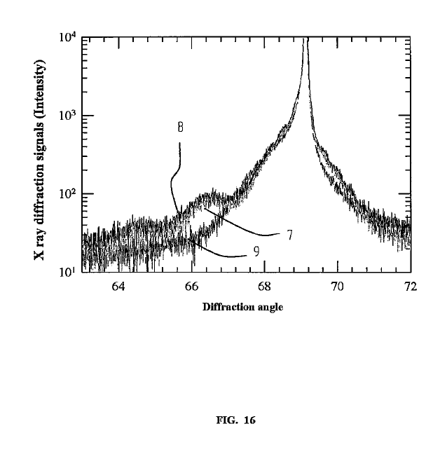

As shown in FIG. 14, after the definition of the gate electrode (45), the next thing is ion implantation of source electrode/drain electrode to form source electrode (46) and drain electrode (47), here arsenic ion is implanted; finally, the microwave activation annealing process is performed with microwave activation frequency of 24.15 GHz and microwave activation temperature of 320° C., and the microwave frequency can also be 24.15 GHz and the annealing temperature can also be 320° C. so as to complete the thin film transistor.

Please refer to FIG. 15, which is used to represent SRP spreading resistance distribution; each point represents how many dopants in each depth are activated; first curve (5) represents the condition of temperature of conventional thermal treatment process, that is, at 900° C. and 30 seconds; second curve (6) represents a condition of maximum temperature of 320° C. and the microwave activation annealing process of the present invention is performed.

Under the mentioned two conditions, activated carrier concentration closely approaches 10²⁰/cm⁻³, that is, each point in the figure represents that 10²⁰ doped atoms are activated, and electron and hole can then be released for the conduction of current; therefore, it can be found from SRP distribution that the microwave thermal activation annealing process as proposed by the present invention not only can effectively activate the dopant atoms to let them move to the lattice point but also the distribution of carrier concentration is relatively narrower as compared to that of the conventional thermal treatment process of temperature of 900° C.; this means that the low temperature activated dopants of the present invention will have more stable status on their distribution locations instead of random walks; hence, the dopant atom diffusion drawback resulted from high temperature activation can then be improved.

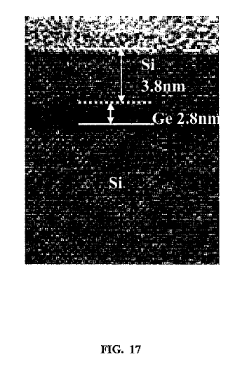

Please refer to FIG. 16, third curve (7) represents a condition of maximum temperature of 320° C. with microwave activation annealing process of the present invention performed; fourth curve (8) is the data for epitaxy; fifth curve (9) represents conventional thermal treatment process of 900° C. and 30 seconds.

As shown in the figure, sample signals from samples of two thermal treatments show great difference; after activation annealing is done with two different ways, under each diffraction angle for the third curve (7) and the fourth curve (8), the strengths of X ray diffraction signals are all very close; however, the trend of the fifth curve (9) and the fourth curve (8) shows great difference.

It can then be seen that the microwave activation annealing process of the present invention won't damage the lattice of epitaxial layer, but under the conventional heat treatment of 900° C. and 30 seconds of activation annealing, the lattice of the epitaxial layer will be created with thermal damage.

Please refer to FIG. 17, which shows the photo of transmission electron microscope of the present invention after microwave activation annealing, it can be seen that sample after the treatment of microwave activation annealing process of the present invention, the lattices at different epitaxial layers do not get any damage; therefore, not only effective activation and annealing can be done, but also no any inter-diffusion will be created.

Although the present invention is disclosed through a better embodiment as above, yet it is not used to limit the present invention, anyone that is familiar with this art, without deviating the spirit and scope of the present invention, can make any kinds of change, revision and finishing; therefore, the protection scope of the present invention should be based on the scope as defined by the following attached “what is claimed”.

1. A microwave activation annealing process, including:
providing a semiconductor process for the formation of a semiconductor device on a substrate;
activation; using a microwave device to perform microwave activation on the semiconductor device, with microwave frequency in the range 2.45 GHz to 24.15 GHz and activation temperature in the range 100° C. to 600° C.;
annealing; using the microwave device to perform microwave annealing on the semiconductor device, with microwave frequency in the range 2.45 GHz to 24.15 GHz and annealing temperature in the range 100° C. to 600° C.

2. The microwave activation annealing process of claim 1 wherein the substrate is silicon-based substrate, compound substrate, glass substrate or flexible substrate.

3. The microwave activation annealing process of claim 2 wherein the substrate is of single layer structure.

4. The microwave activation annealing process of claim 2 wherein the substrate is of a multi-layer structure.

5. The microwave activation annealing process of claim 3 wherein the silicon-based substrate is material of silicon, SiGe or silicon on insulator.

6. The microwave activation annealing process of claim 3 wherein the material of the compound substrate is GaAs, InP, GaAs or AlGaAs.

7. The microwave activation annealing process of claim 3 wherein the flexible substrate is material of polyimide, polyethylene terephthalate, Polyethylene Naphthalate or synthesized paper.

8. The microwave activation annealing process of claim 5 wherein the semiconductor device is nano electronic semiconductor device, metal oxide semiconductor field effect transistor, quantum well, metal semiconductor field effect transistor, field effect transistor with high electron mobility, bipolar junction transistor, light emitting diode, laser diode, thin film transistor or any semiconductor device with PN junction.

9. The microwave activation annealing process of claim 6 wherein the semiconductor device is nano electronic semiconductor device, metal oxide semiconductor field effect transistor, quantum well, metal semiconductor field effect transistor, field effect transistor with high electron mobility, bipolar junction transistor, light emitting diode, laser diode, thin film transistor or any semiconductor device with PN junction.

10. The microwave activation annealing process of claim 7 wherein the semiconductor device is nano electronic semiconductor device, metal oxide semiconductor field effect transistor, quantum well, metal semiconductor field effect transistor, field effect transistor with high electron mobility, bipolar junction transistor, light emitting diode, laser diode, thin film transistor or any semiconductor device with PN junction.

11. The microwave activation annealing process of claim 4 wherein the silicon-based substrate is material of silicon, SiGe or silicon on insulator.

12. The microwave activation annealing process of claim 4 wherein the material of the compound substrate is GaAs, InP, GaAs or AlGaAs.

13. The microwave activation annealing process of claim 4 wherein the flexible substrate is material of polyimide, polyethylene terephthalate, Polyethylene Naphthalate or synthesized paper.
